(19) United States
(12) Patent Application Publication
(10) Pub. No.: US 2023/0328932 A1
(43) Pub. Date: Oct. 12, 2023

(54) INTEGRATED HEAT SPREADER

(71) Applicant: Honeywell International Inc., Charlotte, NC (US)

(72) Inventors: Prashant Hegde, Sriracha (TH); Nishanth Selvaraj, Sriracha (TH); Baskaran Selvan, Sriracha (TH)

(21) Appl. No.: 18/123,122

(22) Filed: Mar. 17, 2023

Related U.S. Application Data
(60) Provisional application No. 63/329,609, filed on Apr. 11, 2022.

(51) Int. Cl. H05K 7/20; B21D 53/04

(52) U.S. Cl. CPC H05K 7/20509; B21D 53/04

(57) ABSTRACT

A heat spreader includes a top surface opposite a bottom surface, a first cavity formed within and extending upwardly from the bottom surface, the first cavity having a depth, a second cavity formed within and extending upwardly from the bottom surface, the second cavity having a depth, and wherein the first depth is greater than the second depth.

### CROSS-REFERENCE TO RELATED APPLICATION

This application claims priority to U.S. Provisional Application No. 63/329,609, filed Apr. 11, 2022, which is herein incorporated by reference in its entirety.

### TECHNICAL FIELD

The present disclosure relates generally to an integrated heat spreader and methods of forming an integrated heat spreader.

### BACKGROUND

Heat spreaders are often used in computer chip packages to draw heat from a chip, semiconductor die, and/or processor and transfer the heat to a heat sink to be dissipated. FIG. 1 illustrates a system established in the art and incorporates the use of heat spreaders. Specifically, a substrate 10 is shown positioned below a chip 12, also referred to as a die, that may be positioned adjacent and below a thermal interface material sheet 14. In some uses, the thermal interface material sheet 14 is composed of various types of polymers, such as silicone, for example. The chip 12 and thermal interface material sheet 14 may be arranged adjacent, and in some embodiments, within a recessed portion of, a heat spreader 20. The heat spreader 20 is arranged adjacent a second layer of the thermal interface material 14. Adjacent the second layer of the thermal interface material 14, the system may include a heat sink 18.

As a result of the above described configuration, during operation of the chip 12, heat generated by the chip 12 is discharged to the heat sink 18 via the heat spreader 20. The heat spreader 20 is able to disperse and spread the heat across the heat spreader 20, facilitating efficient heat transfer to the heat sink 18. In this way, the heat generated by the chip 12 does not cause localized damage to the components in the system. The heat that is dispersed by the heat spreader 20 may then be transferred to the heat sink 18 to be dissipated.

As previously described, in some instances, the heat spreader 20 may have a recess or cavity configured for receiving the chip 12. FIGS. 2A and 2B illustrate an additional embodiments of the heat spreader 20. As illustrated, the heat spreader 20 includes a top side 22 and a bottom side 24, the bottom side 24 having a cavity 26 extending within the bottom side 24. In operation, the chip 12 (FIG. 1) may be arranged within the cavity 26. In these embodiments, it may be desired to have a recess and/or cavity of a shape and size that is optimized to engage with the chip 12 being incorporated into the system.

In manufacture, the heat spreaders 20 may be formed in large volumes by cutting a blank from the sheet or strip of bulk material and by using a combination of stamping processes to impart the desired shape and features to the blank to ultimately produce the desired heat spreader. When the heat spreader 20 includes the cavity 26, the cavity 26 may be formed from punching the material from the blank into a shape and geometry configured for receiving the processor or die in operation. During this process of punching the heat spreader 20 to form the desired shape, the punching force causes cold flow of the material from areas of high pressure into areas of lower pressure. As such, a stamping system can be designed with desired sizes and/or shapes to create the target shape of the cavity 26.

### SUMMARY

The present disclosure provides a heat spreader including a top surface opposite a bottom surface, a first cavity formed within and extending upwardly from the bottom surface, the first cavity having a depth, a second cavity formed within and extending upwardly from the bottom surface, the second cavity having a depth, and wherein the first depth is greater than the second depth.

In one form thereof, the present disclosure provides a heat spreader including a top surface opposite a bottom surface, a first cavity formed within and extending upwardly from the bottom surface, the first cavity having a first depth, a second cavity formed within and extending upwardly from the bottom surface, the second cavity having a second depth, and an outer periphery extending vertically upward from the bottom surface of the heat spreader and extending around at least a portion of the first cavity and at least a portion of the second cavity. The heat spreader further includes wherein the first depth of the first cavity is greater than the second depth of the second cavity.

In another form thereof, the present disclosure provides a method of forming a heat spreader including stamping a central surface of a sheet of material with a die and a press of a stamping system to transfer material outward from a bottom surface of the sheet of material to form a first cavity, stamping the first cavity and a surface adjacent the first surface with a second die and a second press of a second stamping system to transfer material outward from a bottom surface of the sheet of material to form a second cavity, and holding the material of the first cavity and the second cavity constant such that a depth of the first cavity and the second cavity remains constant. The method further includes during the step of holding the material, stamping the outer periphery with a third stamping system to transfer material outward to form a raised surface extending from the outer periphery.

### BRIEF DESCRIPTION OF FIGURES

The above mentioned and other features of this invention, and the manner of attaining them, will become more apparent and the invention itself will be better understood by reference to the following description of embodiments of the invention taken in conjunction with the accompanying drawings, where:

FIG. 1 illustrates a schematic of an example use for a heat spreader;

FIG. 2A illustrates a heat spreader as is known generally in the art;

FIG. 2B illustrates a heat spreader as is known generally in the art;

FIG. 3 illustrates a schematic example press machine that may be used for manufacturing a heat spreader, in accordance with embodiments of the present disclosure;

FIG. 4 illustrates a cross sectional view of a heat spreader, in accordance with embodiments of the present disclosure;

FIG. 5A illustrates a schematic example press machine in use with a sheet of material, in accordance with embodiments of the present disclosure;

FIG. 5B illustrates an enlarged view of a punch and a die of the example press machine of FIG. 5A;

FIG. 6A illustrates a bottom view of a partially completed heat spreader in accordance with embodiments of the present disclosure;

FIG. 6B illustrates an enlarged cross sectional view of a portion of the heat spreader taken along the line 6B-6B of FIG. 6A;

FIG. 7A illustrates a schematic example press machine in use with the partially completed heat spreader of FIG. 6A, in accordance with embodiments of the present disclosure;

FIG. 7B illustrates an enlarged view of a punch and a die of the example press machine of FIG. 7A;

FIG. 8A illustrates a bottom view of a partially completed heat spreader in accordance with embodiments of the present disclosure;

FIG. 8B illustrates an enlarged cross sectional view of a portion of the heat spreader taken along the line 8B-8B of FIG. 8A;

FIG. 9 illustrates a schematic example press machine in use with the partially completed heat spreader of FIG. 8A, in accordance with embodiments of the present disclosure;

FIG. 10A illustrates a bottom view of a heat spreader in accordance with embodiments of the present disclosure;

FIG. 10B illustrates an enlarged cross sectional view of a portion of the heat spreader taken along the line 10B-10B of FIG. 10A;

FIG. 11A illustrates an enlarged cross sectional view of a portion of the heat spreader of FIG. 10B; and

FIG. 11B illustrates an enlarged cross sectional view of a portion of the heat spreader of FIG. 10B.

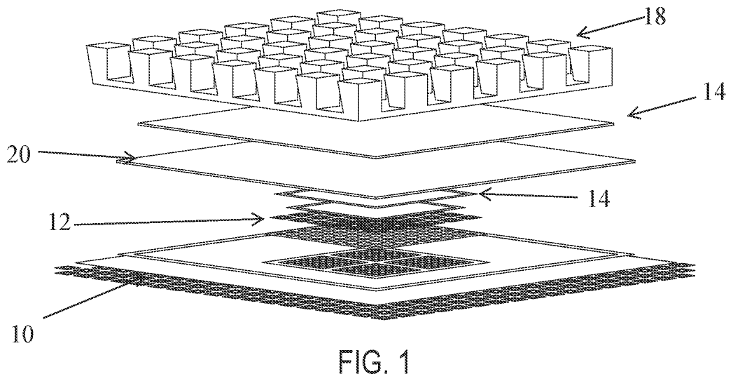

Corresponding reference characters indicate corresponding parts throughout the several views. Unless stated otherwise the drawings are drawn to scale and proportional.

### DETAILED DESCRIPTION

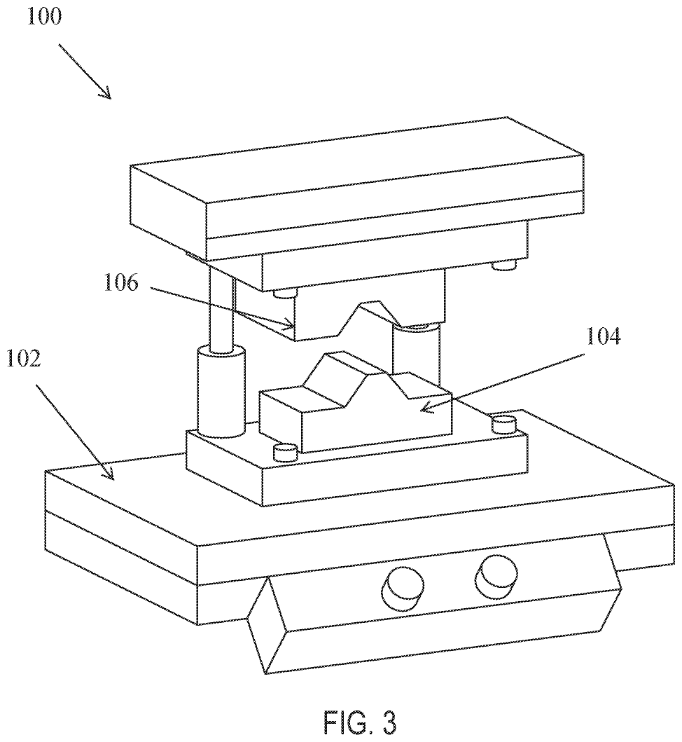

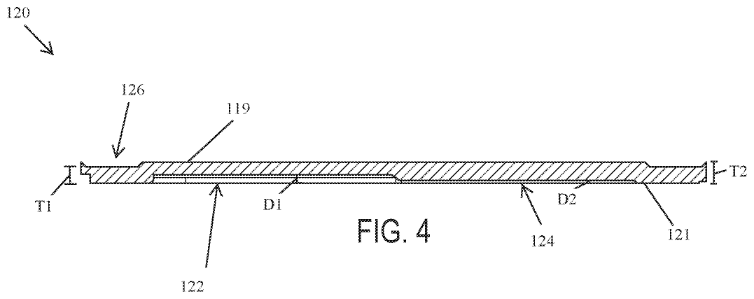

FIG. 3 illustrates a stamping system 100 that may be used for forming a heat spreader, as will be described further with reference to FIGS. 4-11B. Specifically, stamping system 100 includes a plate 102 for securing a die 104 in place. Die 104 and plate 102 are secured such that during the stamping process die 104 and plate 102 remain stationary. Stamping system 100 further includes a punch 106 that is configured for repeated motion up and down in a vertical direction. In operation, a sheet of material, for example a metal, may be placed onto die 104 and punch 106 may be actuated by a ram for downward motion onto the material. During this process, punch 106 is forced downwardly onto the material within stamping system 100 to press the material to conform to the shape of die 104 and/or punch 106. For example, as illustrated, die 104 has a protrusion that extends upward while punch 106 has a corresponding V-shaped groove. As a result of this, once compressed the work piece between die 104 and punch 106 will have a projection matching the shape of the projection of die 104 and the groove of punch 106. While illustrated as having a projection, die 104 and/or punch 106 may have varying shapes and configurations. For example, die 104 and/or punch 106 may have a flat profile, domed profile, or otherwise irregularly shaped profile. Stamping system 100 may be used to form heat spreader 120, further described below, using a die 104 and punch 106 to perform one or more steps to cold-form a blank of material into the desired shape and configuration of heat spreader 120.

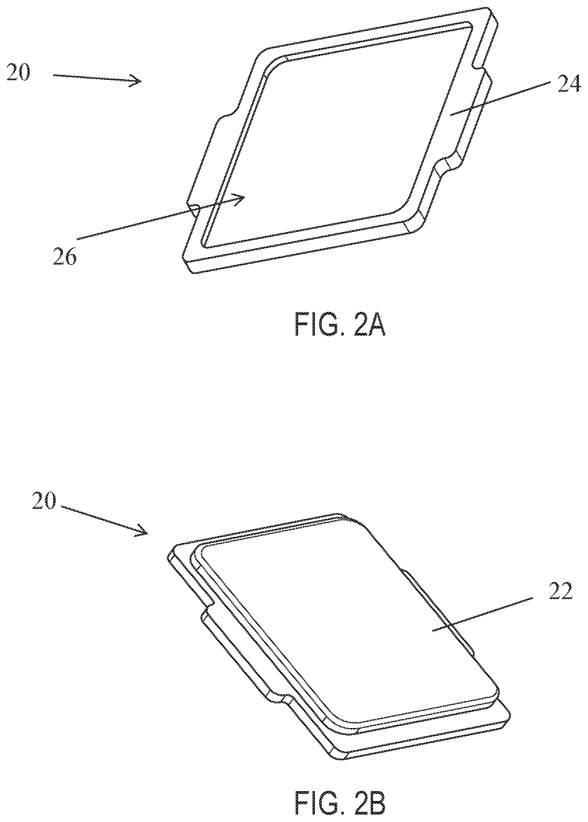

Stamping system 100 may be optimized and used in a process for creating the target shape and/or configuration of heat spreader 20, shown in FIGS. 2A and 2B. In some embodiments, a target shape and/or configuration of heat spreader 20 may include two cavities 24 of different depths. FIG. 4 illustrates the cross section of an exemplary heat spreader 120 that may be formed using a variation of stamping system 100.

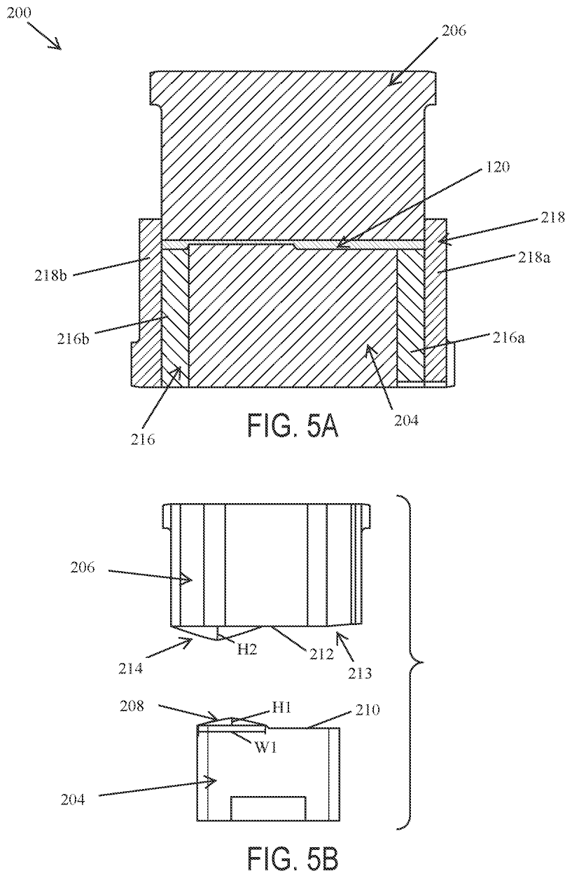

Heat spreader 120 has a top surface 119 positioned opposite a bottom surface 121. Heat spreader 120 includes a first cavity 122 positioned adjacent a second cavity 124, both of which extend from bottom surface 121. As illustrated, first cavity 122 has a depth D1 that may be greater than a depth D2 of second cavity 124. In embodiments, depth D1 may have a value of between approximately 0.10 mm and 3.0 mm while depth D2 may have a value of between approximately 0.05 mm and 1.5 mm. As will be described further herein, heat spreader 120 includes an outer periphery 126 extending around first and second cavities 122, 124. Outer periphery 126 is illustrated as defining a thickness T1 and heat spreader 120 defines an overall thickness T2. Thickness T1 may be less than thickness T2 while in some embodiments, thickness T1 may be approximately equal to thickness T2. The configuration of heat spreader 120 may be particularly advantageous in that it may accommodate chips and/or processors of different thicknesses within the respective cavities 122, 124. Additionally, it may allow for more than one chip and/or processor to be accommodated simultaneously. An exemplary method for forming heat spreader 120 of FIG. 4 will now be described with reference to FIGS. 5A-10B.

FIG. 5A illustrates a variation of stamping system 100, illustratively a stamping system 200. Specifically, stamping system 200 includes a die 204 and a punch 206 to impart a desired shape onto a blank sheet of material. Die 204 and punch 206 may be analogous to die 104 and punch 106 described and shown above with respect to FIG. 3. Die 204 and punch 206 are configured to be actuated vertically into contact with the blank sheet of material to compress the blank sheet between die 204 and punch 206. Specifically, FIG. 5B illustrates die 204 and punch 206 that may be used for a first step in forming heat spreader 120. Die 204 is illustrated as having a dome 208 extending from a left portion of a top surface 210 of dome 208. As illustrated, dome 208 has a width that is approximately half of a width of die 204 however in various other embodiments, the width of dome 208 may be varied. Additionally, as illustrated, dome 208 is illustrated as having a maximum height H1, however, in other embodiments maximum height H1 may be varied. Further, the shape of dome 208 is illustrated as generally conical or paraboloidal, however, various other embodiments may be incorporated. Specifically, dome 208 may have a rectangular, flat, triangular, or otherwise irregular in shape. The various aspects of dome 208, for example the shape, height H1 and width W1, may be varied based on the desired profile of the target heat spreader 120.

Additionally, FIG. 5B illustrates punch 206. Similar to die 204, punch 206 includes a dome 214 extending from a left portion of a bottom surface 212 of punch 206. Further, dome 214 is illustrated having a width which may be approximately half or a little under half of a width of punch 206. The right portion 213 of punch 206 may also be referred to as a negative relief portion, as this configuration ensures that material is able to flow outward when compressed by punch 206 and die 204. Additionally, dome 214 is illustrated as having a height and a generally conical or paraboloidal shape. However, as described relative to dome 208, dome 214 may vary in shape, height, and/or width based on the desired target shape for heat spreader 120. For example, the shape of dome 214 may be generally rectangular, flat, triangular or otherwise irregular in shape.

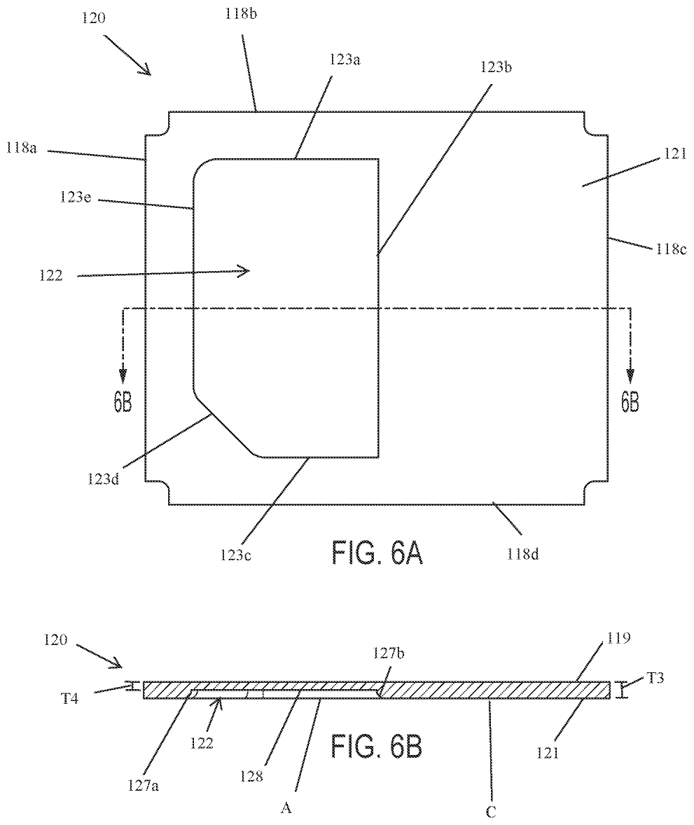

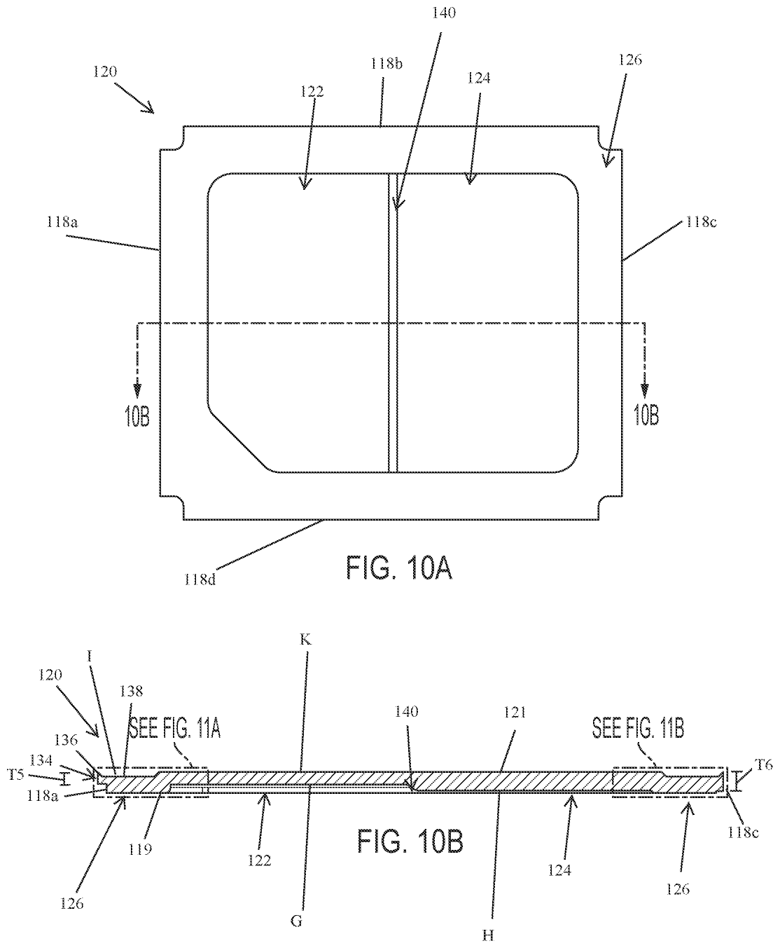

With reference again to FIG. 5A, stamping system 200 is illustrated having a plurality of borders 216, illustratively a first border 216a and a second border 216b, positioned on either lateral side of die 204. Although two borders 216 are shown in the cross-section of FIG. 5A, it is understood that four borders 216 are provided to correspond to each of the four edges around the entire circumference of heat spreader 120. As illustrated, borders 216 extend to a vertical height approximately equal to a vertical height of 204. Additionally, stamping system 200 includes a plurality of outer walls 218, illustratively a first outer wall 218a and a second outer wall 218b, with additional outer walls 218 not shown but corresponding to the two additional borders described above. Outer walls 218 which are positioned laterally adjacent each of borders 216 and when stamping system 200 is clamped down on the sheet of material, outer walls 218 extends laterally adjacent the entirely of side walls of the sheet of material, and laterally adjacent at least a portion of punch 206. In this way, stamping system 200 has a closed tooling configuration. In this way, and as will be described further with reference to FIGS. 6A-6B, when material is pushed and flows out from where die 204 punches the material, the material cannot flow out of the system and past plurality of outer walls 218, and as such the shape of the side walls of the material is maintained to form periphery 126 (FIG. 4). However, in various embodiments, an open tooling system may be desired, as will be described further with reference to FIG. 10A.

As illustrated, when a sheet of material is inserted into stamping system 200 of FIG. 6A and punch 206 is brought downward to stamp into the material, the partially complete heat spreader 120 is formed, as shown in FIG. 6A. FIG. 6A illustrates the partially complete embodiment of heat spreader 120 having first cavity 122. Specifically, die 204 and punch 206 are configured such that when punch 206 contacts and “punches” material of the sheet of material, the material that aligns with dome 208 of modified die 204 is pushed out to cause material flow. As previously disclosed, due to plurality of outer walls 218, stamping system 200 is a closed tooling system. As such, the sizing of domes 208, 214 and the remainder of the surfaces of punch 206 and die 204 are configured to ensure that after the stamping process is completed, first cavity 122 is formed while the remainder of top surface 119 and bottom surface 121 of heat spreader 120 remain flat.

More specifically, with reference to FIGS. 6A-6B, during stamping of the blank sheet of metal, die 204 pushes the material dispersed from surface A to form first cavity 122. Squeezing material from surface A results in partially completed heat spreader 120 having a thickness T3 including depth of first cavity 122, and a thickness T4 omitting the depth of first cavity 122. In embodiments, thickness T3 may have a value of between approximately 0.7 mm and 3.0 mm and thickness T4 may have a value of between approximately 1.0 mm and 4.0 mm. As illustrated in FIGS. 6A-6B, the dispersing of this material results in partially formed heat spreader 120 with first cavity 122 positioned on a left side of heat spreader 120. Partially formed heat spreader 120 is defined by a generally rectangular profile having a first side wall 118a, a second side wall 118b, a third side wall 118c and a fourth side wall 118d. Further, as illustrated, first cavity 122 has a polygonal shape with a first side wall 123a, a second side wall 123b, a third side wall 123c, a fourth side wall 123d and a fifth side wall 123e. FIG. 6B illustrates a cross sectional view of the partially completed heat spreader 120 taken along line 6B-6B of FIG. 6A. As illustrated in cross section of FIG. 6A, first cavity 122 includes curved inner walls 127a, 127b along the edges of the cavity 122, where the curves extend from a bottom surface 128 of first cavity 122 to bottom surface 121 of heat spreader 120. The extent of curvature of curved inner walls 127a, 127b may be due to the domed profile of die 204 and punch 206.

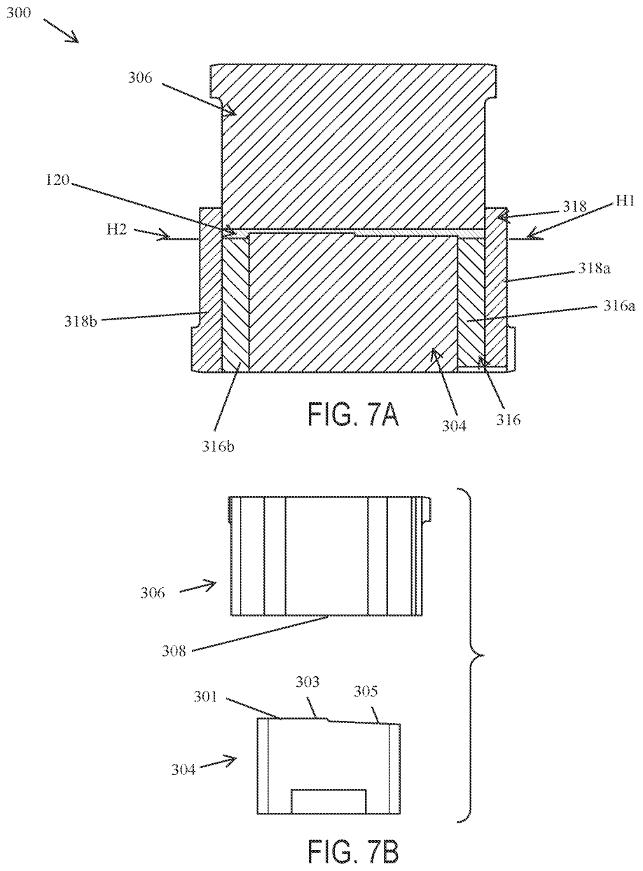

The partially completed heat spreader 120 shown in FIGS. 6A-6B undergoes an additional stamping process to continue towards forming the finished target configuration shown in FIG. 4. Specifically, the partially completed heat spreader 120 of FIG. 6B is inserted into a variation of stamping system 100 (FIG. 3), illustratively stamping system 300. As illustrated, stamping system 300 includes a die 304 and a punch 306 to impart a desired shape onto the partially formed heat spreader 120 of FIG. 6B. Specifically, FIGS. 7A-7B illustrate die 304 and punch 306 that may be used for the second step in forming the target heat spreader 120 shown in FIG. 4. Die 304 is illustrated as having a top surface 301 (FIG. 7B) having a first linear/planar portion 303 on a left portion of die 304 and a second linear/planar portion 305 on a right portion of die 304. As illustrated, second linear/planar portion 305 has a maximum vertical height defined at the junction of first linear/planar portion 303 and second linear/planar portion 305. Additionally, second linear/planar portion 305 is defined with an incline, such that as second portion 305 extends to the right, vertical height of second linear portion 305 decreases and the space afforded for material flow within the cavity between the die 304 and punch 306 increases concomitantly. In other words, the second linear/planar portion 305 defines a negative relief in die 304 which ensures that material is able to flow outward during the stamping process, as will be described further herein. Punch 306 is illustrated having a bottom surface 308 with a linear/planar profile. The linear/planar profile is illustrated as extending straight across and lacks any incline or varying vertical height. However, the profile of die 304 or punch 306 may be altered for the desired application of stamping system 300. For example, vertical height, angle of incline, and/or profile of either top surface 301 of die 304 or bottom surface 308 of punch 306 may be varied.

With reference still to FIG. 7A, stamping system 300 includes a plurality of borders 316, illustratively a first border 316a and a second border 316b positioned on each lateral side of die 304 in operation. Although two borders 316 are shown in the cross-section of FIG. 7A, it is understood that four borders 316 are provided to correspond to each of the four edges around the entire circumference of heat spreader 120. As illustrated, the plurality of borders 316 have a vertical height H1 that is less than a vertical height H2 of die 304. In this way, and as will be described further with reference to FIG. 7B, since borders 316 have a vertical height H1 less than vertical height H2 of die 304, when punch 306 pushes down onto the partially completed heat spreader 120 and die 304 contacts heat spreader 120, the first linear/planar portion 303 of die 304 pushes against first cavity 122 and moves material to the left and the right from first cavity 122. Simultaneously, material is dispersed by second linear/planar portion 305 of die 304 such that the material flows to the right and/or the left. As previously disclosed, die 304 includes a negative relief in second linear/planar portion 305 which may encourage material to flow towards first border 316A.

Still with reference to FIG. 7A, and similar to stamping system 200 of FIGS. 5A-5B, stamping system 300 includes a plurality of outer walls 318 which are positioned laterally adjacent each of borders 316. When stamping system 300 is compressed down on the sheet of material, outer walls 318 extend laterally adjacent the entirety of the side walls of the sheet of material, and laterally adjacent at least a portion of punch 306. In this way, stamping system 300 has a closed tooling configuration. Therefore, when material is pushed and flows out laterally from the area of contact between punch 306 and the workpiece, the material may not flow beyond the plurality of outer walls 318. As such, the shape of side walls 118 of the workpiece (seen in FIG. 6A) is maintained. However, in various embodiments, an open tooling system may be desired, as will be described further with reference to FIG. 10A.

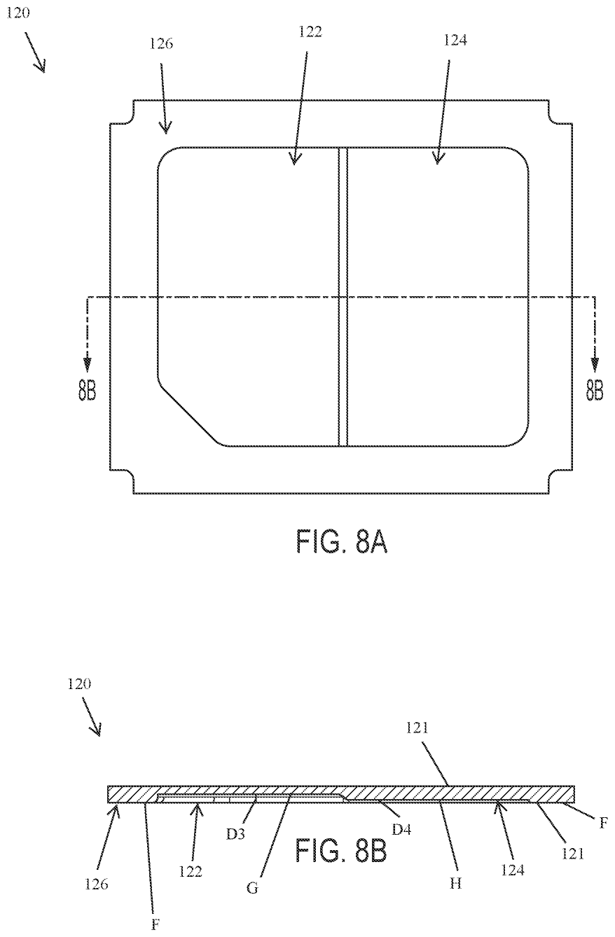

After the above described stamping process, the partially completed heat spreader 120 is defined by the configuration illustrated in FIGS. 8A-8B. Due to the vertical height of second linear/planar portion 305 of die 304 being greater than plurality of walls 316, second cavity 124 may be formed. In other words, material contacted by second linear/planar portion 305 flows outwardly and forms cavity 124. More specifically, and with reference to FIGS. 8A-8B, during the second stamping process, an equal amount of material is squeezed from surface A (FIG. 6B) to surface C (FIG. 6B) to create surface G (FIG. 8B), which acts as a bottom surface of first cavity 122, and surface H (FIG. 8B) which acts as a bottom surface of second cavity 124. As previously discussed, due to the configuration of the plurality of borders 316 and die 304, during this second stamping process, as cavities 122 and 124 are formed, material is squeezed outward to form a surface F on either side of heat spreader 120.

With reference to FIGS. 8A-8B, as material is squeezed to form surface F, an interim phase of outer periphery 126 of heat spreader 120 is formed. Outer periphery 126 extends around first cavity 122 and second cavity 124. Additionally, since first linear/planar portion 303 (FIG. 7B) extends vertically to a vertical position higher than second linear/planar portion 305, first cavity 122 maintains a depth D3 that is greater than a depth D4 of second cavity 124, as illustrated in FIG. 8B.

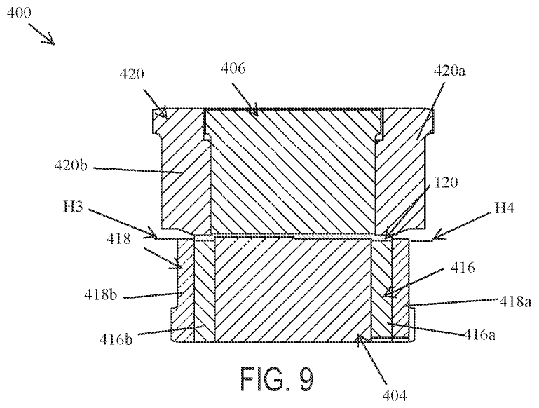

The partially completed heat spreader 120 of FIG. 8A-8B may then undergo an additional stamping process as illustrated in FIG. 9. The partially completed heat spreader 120 of FIGS. 8A-8B is inserted into a stamping system 400. Stamping system 400 may be a variation of stamping system 100 (FIG. 3) and includes die 404, punch 406, and a plurality of borders 416, illustratively a first border 416a and a second border 416b with additional borders formed around the other peripheral edges of heat spreader 120. In embodiments, die 404, punch 406, and plurality of borders 416 are the same, or similar to, die 304, punch 306, and plurality of borders 316 as described with reference to FIGS. 7A-7B. However, stamping system 400 may include a plurality of walls 418, illustratively a first wall 418a and a second wall 418b, that differ than plurality of walls 318 described with reference to stamping system 300 (FIG. 7B). Specifically, plurality of outer walls 418 extend to a vertical height H3 that at a greater vertical position that a vertical height H4 of plurality of borders 416, but extend only partially up the vertical extent of heat spreader 120. In this way, stamping system 400 is in an open tooling configuration, which allows for the material of heat spreader 120 to push out and onto plurality of walls 418 during the stamping process. Further, stamping system 400 additionally includes outer tooling elements 420 which are pressed into partially completed heat spreader 120 when punch 406 is pushed down into partially completed heat spreader 120.

More specifically, with reference to FIGS. 10A-10B, during the third stamping process, the material of surface G and the material of surface H are held such that the material forming their respective geometries is held in place and constrained. During the stamping process, this constraint maintains a substantially constant geometry for surfaces G and H. In other words, the depths D3, D4 of first and second cavities 122, 124 are maintained. As such, during the stamping process, material is pushed down from surface I and causes material to flow into surface K. Additionally, as illustrated, a connecting surface 140 is formed and acts to sharpen the “bridge” or transition between first cavity 122 and second cavity 124. Further, as illustrated best in FIG. 10B, connecting portion 140 may have a generally inclined configuration to connect the bottom surface of first cavity 122 and the bottom surface of second cavity 124.

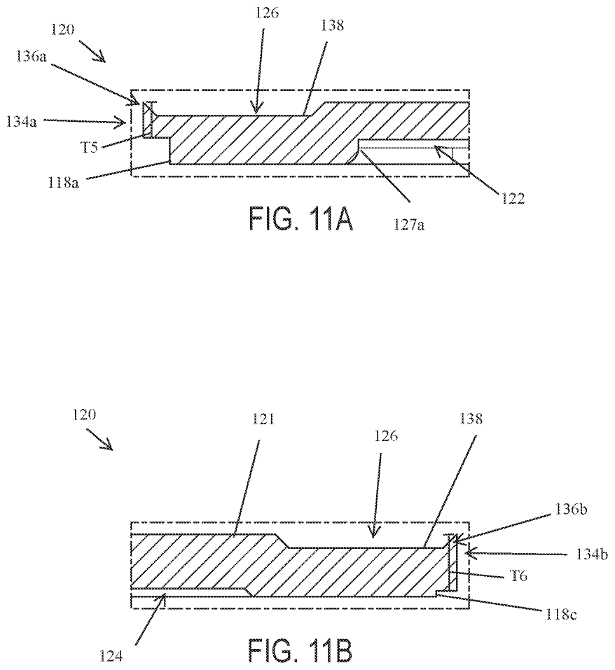

Further, due to outer tooling elements 420 compressing down onto partially completed heat spreader 120, material is pushed outward to form a raised surface around the outer periphery of heat spreader 120. More specifically, material is held in place and constrained to a substantially constant peripheral geometry by borders 416 such that material is squeezed out and upward along the surface of outer tooling elements 420 to create raised surfaces or portions 136a, 136b shown in FIGS. 10B, 11A and 11B, it being understood that these raised surfaces or portions 136 may extend around the entire periphery 126. The above described configuration of stamping system 400 is an open tooling configuration which allows for the material to be pushed out of cavities 122, 124 and towards the sides walls 118 of heat spreader 120, and for the material around periphery 126 to flow outwardly to create raised or protruding portions extending laterally outwardly beyond from the plurality of side walls 118a-d of heat spreader 120.

For example, FIGS. 11A-11B illustrate enlarged views of side walls 118a and 118b of heat spreader 120 in more detail. FIG. 11A illustrates left inner wall of first cavity 122 which is defined by curved inner wall 127a, as previously described with reference to FIG. 6B. Adjacent curved surface 127a of first cavity 122 is outer periphery 126 of heat spreader 120. As illustrated, extending laterally outward beyond outer periphery 126 is a first tail portion 134a of outer periphery 126. More specifically, first tail portion 134a has a thickness T5 that is less than thickness T1 of outer periphery 126 (FIG. 4). Additionally, extending from third side wall 118c is a second tail portion 134b. Second tail portion 134b may have a thickness T6 that is less than thickness T1 of outer periphery 126. Second tail portion 134b also extends laterally beyond third side wall 118c of heat spreader 120. As illustrated, second tail portion 134b may extend laterally outward further than first tail portion 134a extends laterally outward from first side wall 118a. This is due to the configuration of upper walls 420 (FIG. 9A).

Further, as a result of the shape of upper walls 420, during the last step of the stamping process, raised portions 136 extending vertically upward from tailed portions 134a, 134b are formed. More specifically, a first raised portion 136a extends vertically upward from a top surface 138 of outer periphery 126 and from first tail portion 134a and a second raised portion 136b extends vertically upward from a top surface 138 of outer periphery 126 and from second tail portion 134b. As illustrated, raised portions 136 have a generally triangular shape, however various other configurations and/or shapes may be incorporated. Further, stamping system 400 may be modified such that various other desired shapes and configurations are formed within the tailed portions 134 of heat spreader 120 based on the desired use for heat spreader 120, for example the type and/or amount of chips/processors desired for use with heat spreader 120. In some instances, tail portions 134 and/or raised portions 136 may be trimmed away in a further cutting step to finish the heat spreader 120.

While the above method is described for forming heat spreader 120 of FIG. 10A, the method may be varied to produce variations of heat spreader 120. For example, in embodiments heat spreader 120 may include more than two cavities and cavities may have varying profiles and depths.

### Aspects

Aspect 1 is a heat spreader including a top surface opposite a bottom surface, a first cavity formed within and extending upwardly from the bottom surface, the first cavity having a depth, a second cavity formed within and extending upwardly from the bottom surface, the second cavity having a depth, and wherein the first depth is greater than the second depth.

Aspect 2 is the heat spreader of Aspect 1, wherein the heat spreader is defined by a generally rectangular shape having at least four sides.

Aspect 3 is the heat spreader of Aspect 2, wherein the heat spreader includes an outer periphery extending around the first and second cavity, and wherein at least two of the sides of the heat spreader include a raised surface extending at least upwardly from the outer periphery of the heat spreader.

Aspect 4 is the heat spreader of Aspect 3, wherein the raised surface defines a thickness that is less than an overall thickness of the heat spreader.

Aspect 5 is the heat spreader of Aspect 3, wherein the outer periphery defines a thickness that is less than an overall thickness of the heat spreader.

Aspect 6 is the heat spreader of any of Aspects 1-5, wherein the heat spreader is composed of copper.

Aspect 7 is the heat spreader of any of Aspects 1-6, wherein the first cavity is defined by a bottom surface and at least four sides and wherein the first cavity includes a curved surface extending between the bottom surface and the at least four sides.

Aspect 8 is the heat spreader of any of Aspects 1-7, wherein the first cavity is defined by a non-rectangular shape and the second cavity is defined by a generally rectangular shape.

Aspect 9 is the heat spreader of any of Aspects 1-8, wherein the first cavity has a depth of approximately 3.0 mm and the second cavity has a depth of approximately 1.5 mm.

Aspect 10 is the heat spreader of any of Aspects 1-10, wherein an inclined surface extends between and couples the first and the second cavity.

Aspect 11 is a heat spreader including a top surface opposite a bottom surface, a first cavity formed within and extending upwardly from the bottom surface, the first cavity having a first depth, a second cavity formed within and extending upwardly from the bottom surface, the second cavity having a second depth, and an outer periphery extending vertically upward from the bottom surface of the heat spreader and extending around at least a portion of the first cavity and at least a portion of the second cavity. The heat spreader further includes wherein the first depth of the first cavity is greater than the second depth of the second cavity.

Aspect 12 is the heat spreader of Aspect 11, wherein the heat spreader includes an inclined surface extending between and coupling the first cavity and the second cavity.

Aspect 13 is the heat spreader of Aspect 11 or Aspect 12, wherein the depth of the first cavity is approximately 3.0 mm and the depth of the second cavity is approximately 1.5 mm.

Aspect 14 is the heat spreader of any of Aspects 11-13, wherein the outer periphery includes a raised surface extending upwardly and outwardly from the outer periphery.

Aspect 15 is the heat spreader of Aspect 14, wherein the raised surface defines a thickness that is less than a thickness of the heat spreader.

Aspect 16 is a method of forming a heat spreader including stamping a central surface of a sheet of material with a die and a press of a stamping system to transfer material outward from a bottom surface of the sheet of material to form a first cavity, stamping the first cavity and a surface adjacent the first surface with a second die and a second press of a second stamping system to transfer material outward from a bottom surface of the sheet of material to form a second cavity, and holding the material of the first cavity and the second cavity constant such that a depth of the first cavity and the second cavity remains constant. The method further includes during the step of holding the material, stamping the outer periphery with a third stamping system to transfer material outward to form a raised surface extending from the outer periphery.

Aspect 17 is the method of Aspect 16, wherein the depth of the first cavity is greater than the depth of the second cavity.

Aspect 18 is the method of Aspect 16 or Aspect 17, wherein the heat spreader includes at least four sides and the raised surface extends along at least two of the four sides.

Aspect 19 is the method of any of Aspects 16-18, wherein the outer periphery has a thickness that is less than an overall thickness of the heat spreader.

Aspect 20 is the method of Aspect 19, wherein the raised surface extends vertically upward from a top surface of the outer periphery.

While this invention has been described as having exemplary designs, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

1. A heat spreader, comprising:
a top surface opposite a bottom surface;
a first cavity formed within and extending upwardly from the bottom surface, the first cavity having a depth;
a second cavity formed within and extending upwardly from the bottom surface, the second cavity having a depth; and
wherein the first depth is greater than the second depth.

2. The heat spreader of claim 1, wherein the heat spreader is defined by a generally rectangular shape having at least four sides.

3. The heat spreader of claim 2, wherein the heat spreader includes an outer periphery extending around the first and second cavity, and wherein at least two of the sides of the heat spreader include a raised surface extending at least upwardly from the outer periphery of the heat spreader.

4. The heat spreader of claim 3, wherein the raised surface defines a thickness that is less than an overall thickness of the heat spreader.

5. The heat spreader of claim 3, wherein the outer periphery defines a thickness that is less than an overall thickness of the heat spreader.

6. The heat spreader of claim 1, wherein the heat spreader is composed of copper.

7. The heat spreader of claim 1, wherein the first cavity is defined by a bottom surface and at least four sides and wherein the first cavity includes a curved surface extending between the bottom surface and the at least four sides.

8. The heat spreader of claim 1, wherein the first cavity is defined by a non-rectangular shape and the second cavity is defined by a generally rectangular shape.

9. The heat spreader of claim 1, wherein the first cavity has a depth of approximately 3.0 mm and the second cavity has a depth of approximately 1.5 mm.

10. The heat spreader of claim 1, wherein an inclined surface extends between and couples the first and the second cavity.

11. A heat spreader, comprising:
a top surface opposite a bottom surface;
a first cavity formed within and extending upwardly from the bottom surface, the first cavity having a first depth;
a second cavity formed within and extending upwardly from the bottom surface, the second cavity having a second depth;
an outer periphery extending vertically upward from the bottom surface of the heat spreader and extending around at least a portion of the first cavity and at least a portion of the second cavity; and
wherein the first depth of the first cavity is greater than the second depth of the second cavity.

12. The heat spreader of claim 11, wherein the heat spreader includes an inclined surface extending between and coupling the first cavity and the second cavity.

13. The heat spreader of claim 11, wherein the depth of the first cavity is approximately 3.0 mm and the depth of the second cavity is approximately 1.5 mm.

14. The heat spreader of claim 11, wherein the outer periphery includes a raised surface extending upwardly and outwardly from the outer periphery.

15. The heat spreader of claim 14, wherein the raised surface defines a thickness that is less than a thickness of the heat spreader.

16. A method of forming a heat spreader, the method comprising:
stamping a central surface of a sheet of material with a die and a press of a stamping system to transfer material outward from a bottom surface of the sheet of material to form a first cavity;
stamping the first cavity and a surface adjacent the first surface with a second die and a second press of a second stamping system to transfer material outward from a bottom surface of the sheet of material to form a second cavity; and
holding the material of the first cavity and the second cavity constant such that a depth of the first cavity and the second cavity remains constant; and
during the step of holding the material, stamping the outer periphery with a third stamping system to transfer material outward to form a raised surface extending from the outer periphery.

17. The method of claim 16, wherein the depth of the first cavity is greater than the depth of the second cavity.

18. The method of claim 16, wherein the heat spreader includes at least four sides and the raised surface extends along at least two of the four sides.

19. The method of claim 16, wherein the outer periphery has at a thickness that is less than an overall thickness of the heat spreader.

20. The method of claim 19, wherein the raised surface extends vertically upward from a top surface of the outer periphery.
